(19) United States
(12) Patent Application Publication
(10) Pub. No.: US 2013/0249086 A1
(43) Pub. Date: Sep. 26, 2013

(54) CHIP STRUCTURE, CHIP BONDING STRUCTURE USING THE SAME, AND MANUFACTURING METHOD THEREOF

(71) Applicant: RAYDIUM SEMICONDUCTOR CORPORATION, Hsinchu (TW)

(72) Inventor: Ching-San Lin, Wufeng Township (TW)

(73) Assignee: Raydium Semiconductor Corporation, Hsinchu (TW)

(21) Appl. No.: 13/862,383

(22) Filed: Apr. 13, 2013

Related U.S. Application Data
(63) Continuation of application No. 13/089,449, filed on Apr. 19, 2011.

(30) Foreign Application Priority Data
Apr. 20, 2010 (TW) 099112291

(51) Int. Cl. H01L 23/498; H01L 23/00

(52) U.S. Cl. CPC H01L 23/49811; H01L 24/11
USPC 257/737; 438/121

(57) ABSTRACT

A chip structure, a chip bonding structure, and manufacturing methods thereof are provided. The chip structure includes a chip, a plurality of bumps, and an insulation layer. The bumps are disposed on the chip. Each bump has a first bump portion and a second bump portion connected to each other, wherein the first bump portion and the second bump portion have different activities. The bumps are subjected to chemical reaction to form an insulation layer on the surface of one of the first bump portion and the second bump portion which has higher activity, so as to avoid short-circuit between the adjacent bumps.

### CROSS-REFERENCE TO RELATED APPLICATION

This application is a continuation of U.S. patent application Ser. No. 13/089,449, filed Apr. 19, 2011, which application claims priority based on Taiwanese Patent Application No. 099112291, filed on Apr. 20, 2010, the disclosure of which is incorporated herein by reference in its entirety.

### BACKGROUND OF THE INVENTION

1. Field of the Invention

The present invention generally relates to a chip structure, a chip bonding structure using the same, and a manufacturing method thereof. More particularly, this invention relates to a short-circuit-proof chip structure, a chip bonding structure using the same, and a manufacturing method thereof.

2. Description of the Prior Art

With the recent advancement in integrated circuits (ICs), especially for highly delicate IC products such as CPU and memory, the processing technology has been scaled down to the order of tens of nanometers. In a recent announced 22 nm process, the size of a single die on a wafer is minimized to an extent that 2.9 billion transistors can be contained in a nail-size area.

At practice, for a Chip-On-Glass technique used in a LCD module manufacturing process, anisotropic conductive film (ACF) is applied to attach the driver chip onto the glass substrate. FIG. 1 illustrates a schematic view of a conventional connection between the chip and the glass substrate. As shown in FIG. 1, the chip 1 is attached on the glass substrate 3 by means of the anisotropic conductive film 2, wherein the bumps 4 of the chip 1 are coupled to corresponding conducting films 6 of the glass substrate 3 by means of the conducting particles 5 in the anisotropic conductive film 2.

In general, the conducting particles 5 only form electrical connection between the bump 4 and the aligned conducting film 6. However, because the distance between the bumps 4 of the chip 1 is getting smaller as the integration density continuously increases, short-circuit between the bumps 4 is likely occurred due to abnormal connections of the conducting particles 5. As shown in FIG. 1, the conducting particles 5 between two adjacent bumps 4 are connected and form an electrical short-circuit 8. In order to decrease the short-circuit between adjacent bumps 4 caused by the conducting particles 5, a conventional approach is to add an additional photomask associated with a series of processes including lithography, deposition, etching, etc. to mask and form an insulation layer on the bump, consequently increasing the process time and manufacture cost.

### SUMMARY OF THE INVENTION

It is an object of the present invention to provide a chip structure and a manufacturing method thereof, wherein an insulation layer is formed by using the material property of the bump to react the bump with a reactant to prevent short-circuit.

It is another object of the present invention to provide a chip structure and a manufacturing method thereof, wherein an insulation effect is enhanced by oxidizing treatment to prevent short-circuit.

It is another object of the present invention to provide a chip bonding structure and a manufacturing method thereof to prevent short-circuit caused by the conducting particles. Therefore, the time and cost can be economized to satisfy the trend of high efficiency and low cost.

The chip structure of the present invention includes a chip, a plurality of bumps, and an insulation layer. The bumps are disposed on the chip. Each bump has a first bump portion and a second bump portion connected to each other, wherein the first bump portion and the second bump portion have different activities. The bumps are subjected to chemical reaction, such as oxidation, to form an insulation layer on the surface of the higher activity one of the first bump portion and the second bump portion to avoid short-circuit between the adjacent bumps. When a chip having the chip structure is disposed on a glass substrate by an anisotropic conductive film, short-circuit between the adjacent bumps caused by the conducting particles can be prevented.

### BRIEF DESCRIPTION OF THE DRAWINGS

FIG. 1 is a schematic view of a conventional connection between the chip and the glass substrate;

FIG. 2 is a schematic view of the chip structure in an embodiment of the present invention;

FIG. 3 is a schematic view of the chip bonding structure in an embodiment of the present invention; and

FIG. 4 is a schematic view of the chip bonding structure in another embodiment of the present invention.

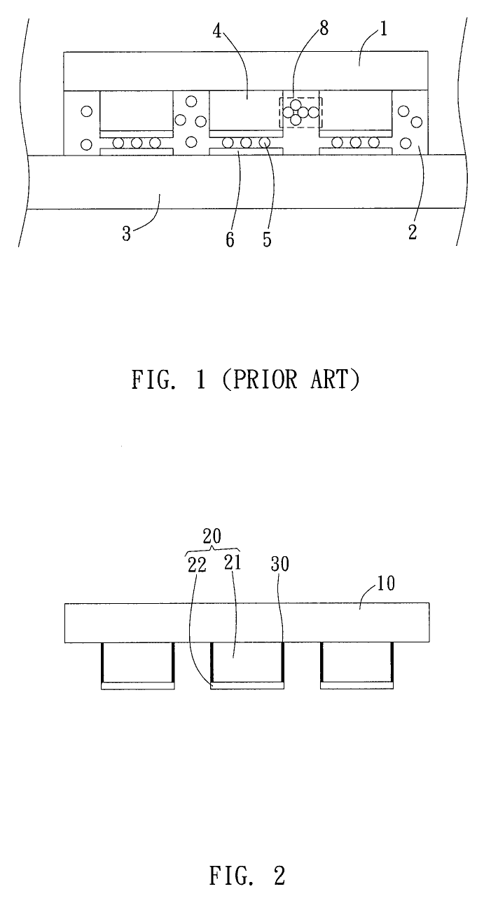

### DETAILED DESCRIPTION OF THE PREFERRED EMBODIMENT

A chip structure, a chip bonding structure, and manufacturing methods thereof are provided in the present invention. In a preferred embodiment, the chip structure and the manufacturing method thereof are used in the processes of making TFT-LCD, semiconductor devices, etc., wherein the chip bonding structure and the manufacturing method thereof can be applied to the Chip-On-Glass technique. In other embodiments, however, the chip structure, the chip bonding structure, and manufacturing methods thereof can be applied to an integrated circuit having a plastic package and its connection.

FIG. 2 is a schematic view of the chip structure in an embodiment of the present invention. As shown in FIG. 2, the chip structure includes a chip 10, a plurality of bumps 20, and an insulation layer 30. The chip 10 can be a die from a semiconductor wafer or a packaged integrated circuit. The bumps 20 are disposed on the chip 10, wherein each bump 20 includes a first bump portion 21 and a second bump portion 22 connected to each other. The activity of the first bump portion is higher than the activity of the second bump portion 22. In a preferred embodiment, the first bump portion 21 is a pillar, while the second bump portion 22 is an inert metal layer formed on the surface of the first bump portion 21. In the preferred embodiment, the first bump portion 21 and the second bump portion 22 are respectively made of copper and gold. In other embodiments, however, the first bump portion 21 can be made of other active metal material such as aluminum; the second bump portion 22 can be made of other inert metal material. The insulation layer 30 has an element identical to the higher activity one of the first bump portion 21 and the second bump portion 22. That is, in this embodiment, the insulation layer 30 has an element identical to the first bump portion 21, such as copper. It is preferred that the whole bump 20 reacts with a reactant to form the insulation layer on a part of the bump 20, i.e. on the surrounding surface of the first bump portion 21 which has the higher activity. The thickness of the insulation layer 30 is thick enough to attain the insulation effect.

During the wafer process of fabricating the chip structure shown in FIG. 2, the chip 10 can be a die on a wafer. In such a case, the first bump portion 21 and the second bump portion 22 of the bump 2 can be formed on the chip 10 by the layer-forming processes including deposition, photolithography, and etching. Due to the difference in activity, i.e. the activities of the first bump portion 21 and the second bump portion 22 are different, the bump 20 can directly react with the reactant so as to form the insulation layer 30 only on the surrounding surface of the first bump portion 21. In other embodiments, a portion of bumps are reacted with the reactant to form staggered isolation layers on the adjacent bumps, so as to have at least one insulation layer between two adjacent bumps to provide the insulation effect (shown in FIG. 4).

In a preferred embodiment, the bump 20 is subjected to oxidation to form an oxide film on the exposed surface of the first bump portion 21, wherein oxygen gas or air is used as the reactant. The oxide film oxidized from the element of the first bump portion 21 serves as the insulation layer 30. In other embodiments, however, nitrogen gas or other gases can be used as the reactant to form a nitride film or other dielectric films on the surface of the first bump portion 21 to serve as the insulation layer 30. In the preferred embodiment, the insulation layer 30 is a copper oxide film formed on the surface of the first bump portion 21. Since copper oxide is electrically insulative, the copper oxide layer on the surface of the first bump portion 21 can provide the insulation effect. The oxidation reaction can be a plasma process performed in a plasma chamber with oxygen gas, or a thermal treatment.

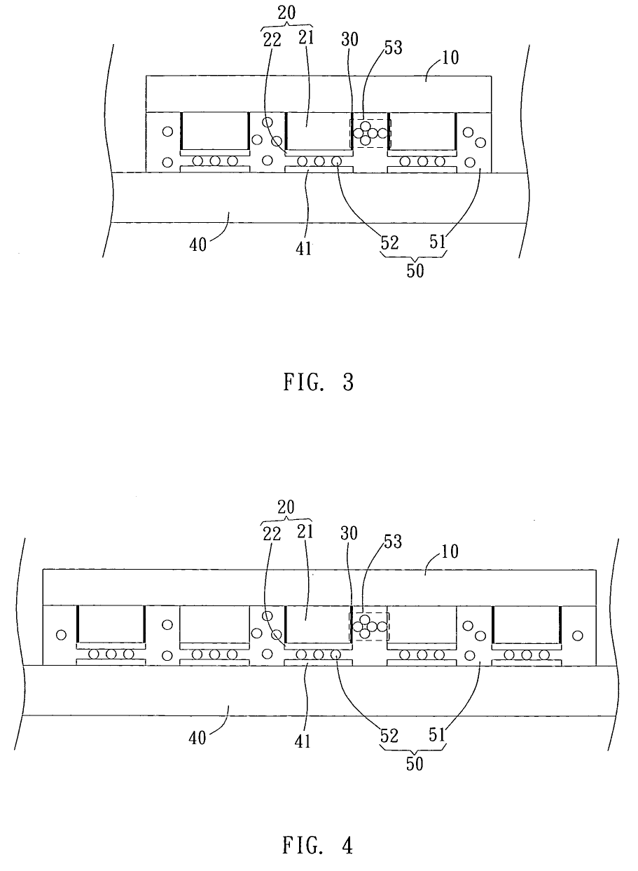

FIG. 3 is a schematic view of the chip bonding structure in an embodiment of the present invention. As shown in FIG. 3, the chip bonding structure includes a chip 10, a plurality of bumps 20, a plurality of insulation layers 30, a substrate 40, and a conducting layer 50, wherein the structure, function, material of the chip 10, the bumps 20, and the insulation layers 30 are similar to those described above. The substrate 40 includes a plurality of conducting films 41 spaced apart from each other. Each bump 20 is preferably aligned to one corresponding conducting film 41. The conducting layer 50 is disposed between the substrate 40 and the chip 10, wherein the conducting layer 50 includes an insulation adhesive and a plurality of conducting particles 52. The second bump portion 22 of the bump 20 and the aligned conducting film 41 is electrically connected by the conducting particles 52. In a preferred embodiment, the substrate 40 is made of glass, wherein the conducting films 41 are metal electrode layers formed on the substrate 40, and the conducting layer 50 is anisotropic conductive film.

As shown in FIG. 3, even though the conducting particles 52 are arranged to form an electrical-path 53 between two adjacent bumps 20, the insulation layers 30 formed on the surrounding surface of the first bump portions 21 prevent short-circuit between the two adjacent bumps 21. Therefore, the possibility of short-circuit between two adjacent bumps 21 can be reduced.

When a chip-on-glass technique is used to fabricate the chip bonding structure shown in FIG. 3, a glass substrate can be provided as the substrate 40, wherein the conducting films 41 can be metal electrode layers formed on the glass substrate. The chip 10 can be fabricated by semiconductor processes and can be a die on a wafer. The bumps 20 can be formed on the chip 10 by the semiconductor processes including deposition, photolithography, and etching. The insulation layer 30 is formed on the surrounding surface of the first bump portion 21 by directly reacting the bump 20 with the reactant, wherein the activity of the first bump portion 21 is higher than the activity of the second bump portion 22. The substrate 40 and the chip 10 are connected by the conducting layer 50 such as anisotropic conductive film, wherein a portion of conducting particles 52 of the conducting layer 50 are placed between the bump 20 and the aligned conducting film 41 to electrically connect the bump 20 with the aligned conducting film 41.

The insulation layer formed on the surrounding surface of the first bump portion of the bump prevents short-circuit between adjacent bumps. Therefore, the possibility of short-circuit between two adjacent bumps is reduced. Besides, the time and cost spending on the processes associated with the additional photomask to form an insulation layer in the prior arts can be efficiently saved to satisfy the requirements of high efficiency and low cost.

In the above mentioned embodiments, the insulation layers 30 are formed on every bump 20. However, in other embodiments, the insulation layer 30 can be formed on a portion of bumps 20. As shown in FIG. 4, staggered isolation layers 30 are formed on the adjacent bumps, so as to have at least one insulation layer 30 between two adjacent bumps 20 to provide the insulation effect. Hence, the electrical-path 53 formed by the conductive particles 52 does not cause any short-circuit between two adjacent bumps 20.

Although the preferred embodiments of the present invention have been described herein, the above description is merely illustrative. Further modification of the invention herein disclosed will occur to those skilled in the respective arts and all such modifications are deemed to be within the scope of the invention as defined by the appended claims.

1. A chip structure, comprising:
a chip;
at least one bump disposed on the chip, wherein the bump includes a first bump portion and a second bump portion connected to each other, wherein the first bump portion and the second bump portion have different activities; and
an insulation layer having an element identical to the element in a higher activity one of the first bump portion and the second bump portion, wherein the insulation layer is formed on the surface of the higher activity one of the first bump portion and the second bump portion.

2. A chip bonding structure, comprising:
a substrate including a plurality of conducting films spaced apart from each other;
a chip including a plurality of bumps respectively aligned to the plurality of conducting films; and
a conducting layer disposed between the substrate and the chip, wherein the conducting layer includes a plurality of conducting particles electrically connecting the bump and the aligned conducting film;
wherein a portion of at least one of the plurality of bumps reacts with a reactant to form an insulation layer on the surface of the portion.

3. The chip bonding structure of claim 2, wherein the bump includes a first bump portion and a second bump portion connected to each other, wherein the first bump portion and the second bump portion have different activities, wherein the insulation layer is formed on the surface of a higher activity one of the first bump portion and the second bump portion.

4. The chip bonding structure of claim 3, wherein the activity of the first bump portion is higher than the activity of the second bump portion, wherein the second bump portion includes an inert metal layer electrically connected to the conducting film by the conducting particles.

5. The chip bonding structure of claim 4, wherein the inert metal layer includes gold, wherein the first bump portion includes copper.

6. A chip structure manufacturing method, comprising:
providing a chip;
disposing at least one bump on the chip, wherein the bump includes a first bump portion and a second bump portion connected to each other, wherein the second bump portion is disposed at an end away from the chip, wherein the activity of the first bump portion is higher than the activity of the second bump portion; and
reacting the bump with a reactant to form an insulation layer only on the surface of the first bump portion.

7. A chip bonding structure manufacturing method, comprising:
providing a substrate including a plurality of conducting films spaced apart from each other;
providing a chip including a plurality of bumps respectively aligned to the plurality of conducting films;
reacting a portion of at least one of the plurality of bumps with a reactant to form an insulation layer on the surface of the portion; and
disposing a conducting layer between the substrate and the chip, wherein the conducting layer includes a plurality of conducting particles electrically connecting the bump and the aligned conducting film.

8. The chip bonding structure manufacturing method of claim 7, wherein the bump includes a first bump portion and a second bump portion connected to each other, wherein the first bump portion and the second bump portion have different activities, wherein the insulation layer forming step includes oxidizing the bump to form the insulation layer on the surface of a higher activity one of the first bump portion and the second bump portion.

9. The chip bonding structure manufacturing method of claim 8, wherein the activity of the first bump portion is higher than the activity of the second bump portion, wherein the conducting layer disposing step includes electrically connecting the second bump portion to the conducting film by the conducting particles.

10. The chip bonding structure manufacturing method of claim 8, wherein the second bump portion includes gold, wherein the first bump portion includes copper.
